(19) United States
(12) Patent Application Publication
(10) Pub. No.: US 2026/0050012 A1
(43) Pub. Date: Feb. 19, 2026

(54) TEST AND/OR MEASUREMENT INSTRUMENT, AND OSCILLOSCOPE

(71) Applicant: Rohde & Schwarz GmbH & Co. KG, Muenchen (DE)

(72) Inventors: Martin Stumpf, Muenchen (DE); Thomas Kuhwald, Muenchen (DE); Wolfgang Herbordt, Muenchen (DE); FranciscoJavier GarciaGomez, Muenchen (DE); Bernd Rottler, Muenchen (DE); Sven Rheindt, Muenchen (DE); Nico Toender, Muenchen (DE)

(21) Appl. No.: 18/807,123

(22) Filed: Aug. 16, 2024

(51) Int. Cl. G01R 13/02; G01R 1/067

(52) U.S. Cl. CPC G01R 13/029; G01R 1/06788; G01R 13/0254; G01R 13/0272

(57) ABSTRACT

An instrument for measuring differential signals includes a plurality of pairs of input channels and a real-time circuit. The plurality of pairs of input channels each include two input channels configured to receive a plurality of analog input signals. The real-time circuit includes a plurality of pairs of analog-to-digital converters (ADCs), and a real-time processing circuit. Each of the plurality of pairs of ADCs is allocated to one of the pairs of input channels, and is configured to digitize one of the analog input signals for obtaining a digitized input signal. The real-time processing circuit has a first operational mode and a second operational mode. The real-time processing circuit is configured to process digitized signals of a single pair of ADCs in the first operational mode and is configured to process the digitized signals of two different pairs of ADCs in the second operational mode.

### FIELD OF THE DISCLOSURE

Embodiments of the present disclosure generally relate to a test and/or measurement instrument for measuring differential signals. Embodiments of the present disclosure further relate to an oscilloscope.

### BACKGROUND

For measuring differential signals, it is known in the state of the art to receive and process the two signals via two channels of a test and/or measurement instrument. These two signals are typically digitized by two analog-to-digital converters, and the resulting digitized signals are processed by a hardware processing circuit.

In order to process different sample rates of the digitized signals, it is currently necessary to process signals having different sample rates with different hardware processing circuits, which increases the manufacturing costs of the test and/or measurement instrument due to the additional hardware required.

Thus, there is a need for a test and/or measurement instrument and for an oscilloscope that have reduced hardware requirements for processing different types of signals

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a test and/or measurement instrument for measuring differential signals. In an embodiment, the test and/or measurement instrument comprises a plurality of pairs of input channels and a real-time circuit. The plurality of pairs of input channels each comprise two input channels. The input channels are configured to receive a plurality of analog input signals. The real-time circuit comprises a plurality of pairs of analog-to-digital converters (ADCs) and at least one real-time processing circuit. In an embodiment, each of the plurality of pairs of ADCs is allocated to one of the pairs of input channels, wherein each ADC is configured to digitize one of the analog input signals so as to obtain a digitized input signal. The at least one real-time processing circuit has a first operational mode and a second operational mode. In an embodiment, the at least one real-time processing circuit is configured to process digitized signals of a single pair of ADCs in the first operational mode and is configured to process the digitized signals of two different pairs of ADCs in the second operational mode.

The term “plurality” is understood to reference a quantity or number. In this regard, the term “plurality” is meant to be any number that is more than one, for example, two, three, four, five, etc.

The term “real-time” is understood to denote processing without intermediate saving of the respective signal(s) in a memory such as an acquisition memory. Accordingly, the real-time circuit processes the plurality of analog input signals in real time, thereby obtaining a plurality of output signals without intermediate saving in a memory. The output signals of the real-time circuit may, however, be saved in a memory, e.g. in an acquisition memory, for later post-processing.

The test and/or measurement instrument according to embodiments of the present disclosure is based on the idea to provide a more flexible signal routing, such that the same hardware components can be used in different operational modes.

In an embodiment, as will be described in more detail below, the test and/or measurement instrument allows to process digitized signals having different sample rates with the same hardware components, for example with the same at least one real-time processing circuit, thereby reducing the manufacturing costs of the test and/or measurement instrument.

This is achieved, for example, by providing a flexible routing between the plurality of ADCs and the at least one real-time processing circuit. For instance, instead of allowing the at least one real-time processing circuit to only process digitized signals from one assigned pair of ADCs, digitized signals from different pairs of ADCs can be forwarded to and processed by the at least one real-time processing circuit, namely in the second operational mode.

As will be described in more detail below, this allows to process digitized signals having different sample rates using the same hardware components, for example the same at least one real-time processing circuit. In an embodiment, the same hardware components, for example the same at least one real-time processing circuit, can be utilized even if the digitized signals processed correspond to a differential signal.

For example, in the first operational mode, the at least one real-time processing circuit may process two digitized signals from a single pair of ADCs that each digitize a different analog input signal with a certain sample rate. In the second operational mode, the at least one real-time processing circuit may process digitized signals from two different pairs of ADCs, wherein each pair of ADCs digitizes a different analog input signal in an interleaved sampling operation, thereby doubling the sample rate of digitizing the analog input signals.

It is emphasized that the at least one real-time processing circuit does not perform the digitization of the corresponding analog input signals in either of the operational modes, which is performed by the plurality of ADCs.

In an embodiment, the digitized input signals received by the at least one real-time processing circuit may be or constitute a differential signal.

In an embodiment, the at least one real-time processing circuit may be configured to process the differential signal, thereby obtaining at least one output signal. The at least one output signal may comprise, for example, a sum of the digitized input signals and/or a difference of the digitized input signals processed.

In an embodiment, the test and/or measurement instrument may be an oscilloscope, for example a digital oscilloscope. However, it is to be understood that the test and/or measurement instrument may also be established as any other suitable type of test and/or measurement instrument, such as a vector network analyzer, a spectrum analyzer, or a signal analyzer.

In an embodiment, the plurality of pairs of ADCs comprise a first pair of ADCs being allocated to the at least one real-time processing circuit, wherein the first pair of ADCs comprises a first ADC and a second ADC. In the first operational mode, the first ADC is configured to digitize a first analog input signal, thereby obtaining a first digitized input signal, and the second ADC is configured to digitize a second analog input signal being different from the first analog input signal, thereby obtaining a second digitized input signal. The real-time processing circuit is configured to receive the first digitized input signal and the second digitized input signal. In the second operational mode, the first ADC and the second ADC are configured to jointly digitize a single analog input signal, thereby obtaining a first digitized input signal and a second digitized input signal both corresponding to the single analog input signal, wherein the real-time processing circuit is configured to receive the first digitized input signal and the second digitized input signal.

In other words, in the first operational mode, different analog input signals are digitized by the first pair of ADCs with a certain sample rate. For example, the first analog input signal and the second analog input signal may establish a differential signal.

On the other hand, in the second operational mode, the first ADC and the second ADC are operated in an interleaved manner, such that the single analog input signal is digitized with double the sample rate compared to the first operational mode. The single analog input signal may correspond to a portion of a differential signal, for example to one of two signals constituting the differential signal.

In an embodiment, in the second operational mode, a further analog input signal may be jointly digitized by a second pair of ADCs, wherein the further analog input signal may be the other signal of the two signals constituting the differential signal.

Thus, the differential signal is digitized by two pairs of ADCs, namely by the first pair of ADCs and the second pair of ADCs, in the second operational mode, for example digitized with double the sample rate compared to the first operational mode.

According to an aspect of the present disclosure, the test and/or measurement instrument comprises, for example, a trigger circuit. In an embodiment, the trigger circuit is configured to trigger on at least one output signal of the at least one real-time processing circuit. Thus, a trigger functionality is provided, even if the analog input signals processed by the test and/or measurement instrument correspond to a differential signal. For example, the trigger functionality provided allows to provide a stable time-domain graphical representation of the analog input signals processed.

In another embodiment of the present disclosure, the at least one real-time processing circuit comprises at least one of an adder circuit, a subtraction circuit, or an equalizer circuit. Accordingly, an output signal or output signals of the at least one real-time processing circuit may comprise, for example, a sum of the digitized input signals, a difference of the digitized input signals, and/or equalized digitized input signals. In an embodiment, the same adder circuit(s), subtraction circuit(s), and/or equalizer circuit(s) may be used in both the first operational mode and the second operational mode.

According to another aspect of the present disclosure, a first input channel of the plurality of pairs of input channels, for example, is connectable to a first measurement probe and a second input channel of the plurality of pairs of input channels, for example, is connectable to a second measurement probe. Accordingly, a first analog input signal received by the first input channel may be picked up by the first measurement probe, while a second analog input signal received by the second input channel may be picked up by the second measurement probe.

In an embodiment, the first measurement probe may be different from the second measurement probe, i.e. the first measurement probe and the second measurement probe may be physically different measurement probes. However, it is also conceivable that the first measurement probe and the second measurement probe may together establish a single differential measurement probe.

In an embodiment, the first input channel and the second input channel may belong to the same pair of input channels, for example if the at least one real-time processing circuit is operated in the first operational mode. Alternatively, the first input channel and the second input channel may belong to different pairs of input channels, for example if the at least one real-time processing circuit is operated in the second operational mode.

Another aspect of the present disclosure provides, for example, that the test and/or measurement instrument comprises a plurality of real-time processing circuits. In an embodiment, the plurality of real-time processing circuits are configured to process digitized input signals corresponding to N input channels with a respective predetermined sample rate in the first operational mode, wherein the at least one real-time processing circuit is configured to process digitized input signals corresponding to N/2 input channels with double the predetermined sample rate in the second operational mode, and wherein N is an integer being equal to or greater than 2. Therein, the same hardware components, namely the same plurality of real-time processing circuits, are utilized in both the first operational mode and the second operational mode. Accordingly, no additional hardware is required for digitizing and processing the analog input signals with different sample rates. Accordingly, the manufacturing costs of the test and/or measurement instrument or reduced considerably.

In an embodiment, the real-time circuit may comprise a plurality of real-time processing circuits, wherein each of the real-time processing circuits is connected or connectable to two input channels, and wherein each real-time processing circuit is configured to receive two digitized input signals being associated with one or two of the plurality of input channels. For example, in the first operational mode, the real-time processing circuit is connected to two input channels of a single pair of input channels, namely via the corresponding pair of ADCs. In the second operational mode, the real-time processing circuit is connected to 2 input channel that belong to two different pairs of input channels, namely via the two corresponding pairs of ADCs.

In an embodiment, the at least one real-time processing circuit is configured to receive 2P=2S/f_{c} input signal samples, wherein the at least one real-time processing circuit is configured to output 2P=2S/f_{c} output signal samples, wherein S is a respective sample rate of the respective ADCs, wherein P is a parallelism of the at least one real-time processing circuit, and wherein f_{c} is a clock rate of the at least one real-time processing circuit. Accordingly, the number of samples that can be processed by the at least one real-time processing circuit per clock cycle matches the number of samples received by the at least one real-time processing circuit from two ADCs each having a sample rate S. Thus, it is ensured that all samples output by the ADCs can be processed in real time.

In another embodiment, the plurality of pairs of ADCs comprise a first pair of ADCs, wherein the first pair of ADCs comprises a first ADC and a second ADC. In the first operational mode, the at least one real-time processing circuit is configured to receive P=S/f_{c} input signal samples corresponding to a first analog input signal from the first ADC and P=S/f_{c} input signal samples corresponding to a second analog input signal from the second ADC. In the second operational mode, the at least one real-time processing circuit is configured to receive P=S/f_{c} input signal samples corresponding to a first analog input signal from the first ADC and P=S/f_{c} input signal samples corresponding to the first analog input signal from the second ADC. In other words, in the first operational mode, the 2P input signal samples received by the at least one real-time processing circuit correspond to two different analog input signals received and digitized by the first ADC and the second ADC. In the second operational mode, the 2P input signal samples received by the at least one real-time processing circuit correspond to a single analog input signal received and digitized by the first ADC and the second ADC in an interleaved manner.

According to an aspect of the present disclosure, the test and/or measurement instrument comprises, for example, a synchronization circuit. In an embodiment, the synchronization circuit is configured to synchronize digitized input signals forwarded to the at least one real-time processing circuit. This way, a correct processing of the digitized input signals, for example of the digitized input signals corresponding to a differential signal, is ensured. For example, it is ensured that samples of different digitized input signals are correctly aligned in time domain.

According to a further aspect of the present disclosure, the test and/or measurement instrument further comprises, for example, a detection circuit. In an embodiment, the detection circuit is configured to determine whether different digitized input signals are forwarded to the at least one real-time processing circuit in sync. Accordingly, misalignments of different digitized input signal being processed by the at least one real-time processing circuit can be detected by the detection circuit and can be corrected if necessary. Thus, the measurement accuracy is enhanced, for example for processing differential signals.

Embodiments of the present disclosure further provide an oscilloscope. The oscilloscope comprises a plurality of input channels and a real-time circuit. The plurality of input channels are each configured to receive an analog input signal. The real-time circuit comprises a plurality of analog-to-digital converters, ADCs, wherein the plurality of ADCs are connected or connectable to the plurality of input channels. The oscilloscope is configured to selectively group the plurality of input channels into a first channel group and a second channel group. In the first channel group, one ADC of the plurality of ADCs is allocated per input channel belonging to the first channel group. In the second channel group, at least two ADCs of the plurality of ADCs are allocated per input channel belonging to the second channel group.

In an embodiment, for an input channel belonging to the first channel group, the respective input channel may receive an analog input signal which may then be digitized by a single ADC allocated to that input channel. For an input channel belonging to the second channel group, the respective input channel may receive an analog input signal which is then digitized by the plurality of ADCs allocated to that channel in an interleaved manner, i.e. with a higher sample rate.

In an embodiment, the different channel groups provide different sample rates. Therein, the same hardware resources can be used for the different sample rates, such that the manufacturing costs of the oscilloscope are reduced. In other words, the input channels may be selectively grouped into “interleaved channels” belonging to the second channel group, and “non-interleaved channels” belonging to the first channel group.

Thus, the oscilloscope according to embodiments of the present disclosure is also capable of a mixed operation mode, wherein one or more channels are assigned to the first channel group, and wherein two or more inputs channels are simultaneously assigned to the second channel group. Thus, different analog input signals may be processed by the oscilloscope with different sample rates at the same time, thereby providing a high amount of flexibility for processing different signals simultaneously.

According to an aspect of the present disclosure, 2ⁿ ADCs of the plurality of ADCs, for example, are allocated per input channel belonging to the second channel group, wherein n is an integer greater than or equal to 1. In other words, the respective input channel may receive an analog input signal which is then digitized by 2′ ADCs allocated to that channel. Thus, the sampling rate for that input channel is increased by a factor of 2′.

In an embodiment, the at least two ADCs allocated per input channel belonging to the second channel group are configured to jointly digitize a single analog input signal received by the respective input channel belonging to the second channel group. In other words, the at least two ADCs are operated in an interleaved manner, such that the sample rate of digitizing the analog input signal is increased, namely by a factor corresponding to the number of ADCs jointly digitizing the single analog input signal.

In an embodiment, the first channel group and the second channel group may be configured to be operated independent of each other. Accordingly, different analog input signals can be digitized and processed by the oscilloscope with different sample rates independent of each other. This greatly enhances the versatility of the oscilloscope.

According to another aspect of the present disclosure, the real-time circuit, for example, further comprises at least one real-time processing circuit. In an embodiment, the at least one real-time processing circuit is configured to process digitized input signals corresponding to the first channel group and/or digitized input signals corresponding to the second channel group. The explanations given above with respect to the real-time processing circuit of the test and/or measurement instrument likewise apply to the real-time processing circuit of the oscilloscope according to the present disclosure. In an embodiment, the real-time processing circuit may be established according to any one of the variants described above.

In an embodiment, the real-time circuit may further comprise at least one high-rate acquisition circuit, wherein the at least one high-rate acquisition circuit is connected to the ADCs allocated to the second channel group, and wherein the high-rate acquisition circuit is configured to interleave digitized input signals received from the ADCs allocated to the second channel group, thereby obtaining an interleaved digitized input signal. The high-rated acquisition circuit may be a dedicated circuit that is specifically configured to interleave a plurality of digitized input signals. This way, a fast and precise processing of the plurality of digitized input signal to be interleaved is ensured.

In another embodiment, the at least one high-rate acquisition circuit is configured to apply a channel compensation to the interleaved digitized input signal, thereby obtaining a compensated interleaved digitized input signal, and wherein the at least one high-rate acquisition circuit is configured to de-interleave the compensated interleaved digitized input signal, thereby obtaining a plurality of compensated digitized input signals. For example, the high-rate acquisition circuit is configured to compensate channel effects, which are also called analog frontend effects, of the corresponding input channel(s) by applying the channel compensation. Thus, the measurement accuracy is enhanced.

In an embodiment, the oscilloscope may further comprise a plurality of acquisition memories, wherein the at least one high-rate acquisition circuit is connected to the plurality of acquisition memories, and wherein the plurality of acquisition memories is configured to store the plurality of compensated digitized input signals.

In an embodiment, the plurality of acquisition memories may be the acquisition memories that are allocated to the individual input channels in a conventional operation, i.e. in a non-interleaved operation of the oscilloscope.

In other words, the same acquisition memories are utilized irrespective of whether the oscilloscope is operated with all input channels allocated to the first channel group, with all input channels allocated to the second channel group, or in a mixed operational mode with some input channels allocated to the first channel group and some input channels allocated to the second channel group.

Thus, no additional acquisition memories are necessary in spite of the additional flexibility of the oscilloscope according to the present disclosure regarding possible sample rates, thereby reducing the manufacturing costs of the oscilloscope.

In an embodiment, the oscilloscope may further comprise a plurality of post-processing circuits and a distribution circuit. In an embodiment, the distribution circuit is interconnected between the plurality of acquisition memories and at least one of the post-processing circuits, and wherein the distribution circuit is configured to forward the plurality of compensated digitized input signals to the at least one of the post-processing circuits. In an embodiment, the plurality of post-processing circuits may be the post-processing circuits that are allocated to the individual input channels in a conventional operation, i.e. non-interleaved operation of the oscilloscope.

In other words, the same post-processing circuit(s) is/are utilized irrespective of whether the oscilloscope is operated with all input channels allocated to the first channel group, with all input channels allocated to the second channel group, or in a mixed operational mode with some input channels allocated to the first channel group and some input channels allocated to the second channel group.

Thus, no additional post-processing circuits are necessary in spite of the additional flexibility of the oscilloscope according to the present disclosure regarding possible sample rates, thereby reducing the manufacturing costs of the oscilloscope.

In an embodiment, the distribution circuit may be configured to forward the plurality of compensated digitized input signals to exactly one of the post-processing circuits

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a representative test and/or measurement system comprising a test and/or measurement instrument according to an embodiment of the present disclosure;

FIG. 2 schematically shows an example embodiment of a real-time circuit of the test and/or measurement instrument of FIG. 1 in more detail;

FIG. 3 schematically shows an example embodiment of the real-time processing circuits of the real-time circuit of FIG. 2 in more detail; and

FIG. 4 schematically shows an example embodiment of a real-time circuit and a post-processing circuit of the test and/or measurement instrument of FIG. 1 in more detail.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

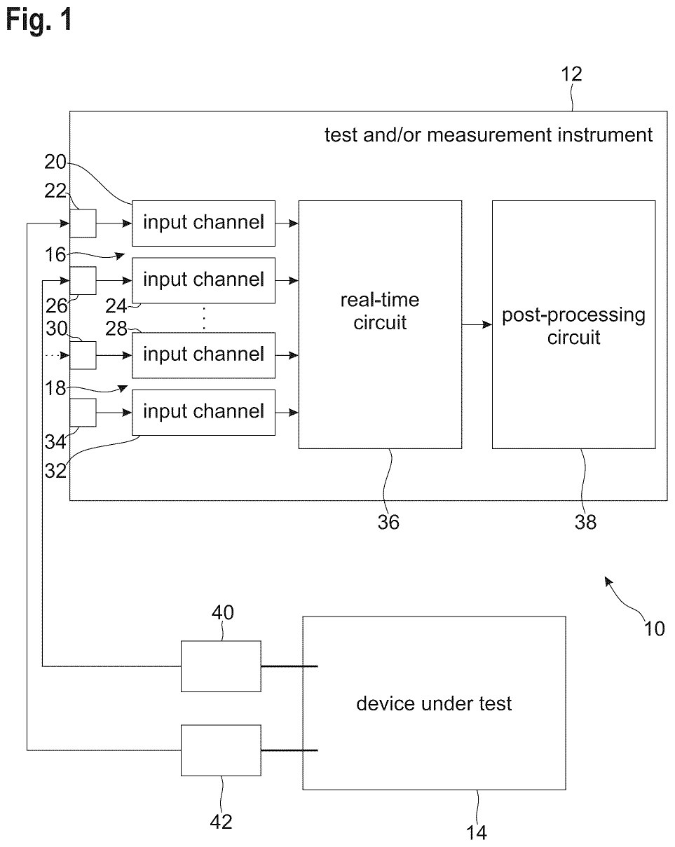

FIG. 1 schematically shows a representative test and/or measurement system 10 comprising a test and/or measurement instrument 12 and a device under test 14. In general, the test and/or measurement instrument 12 is configured to perform tests and/or measurements on the device under test 14, for example in order to assess a performance or a correct functionality of the device under test 14.

For instance, the test and/or measurement instrument 12 may be an oscilloscope, for example a digital oscilloscope. However, it is to be understood that the test and/or measurement instrument 12 may be established as any other suitable type of test and/or measurement instrument, such as a vector network analyzer, a spectrum analyzer, or a signal analyzer.

The device under test 14 may be any type of electronic device or electronic circuit being configured to generate and/or process electrical signals, for example differential signals.

In the example embodiment shown in FIG. 1, the test and/or measurement instrument 12 comprises a first pair of input channels 16 and a second pair of input channels 18. However, as is indicated by the ellipses, the test and/or measurement instrument 12 may comprise an arbitrary further number of pairs of input channels.

Without restriction of generality, the example case of the test and/or measurement instrument 12 comprising two pairs of input channels is described hereinafter.

In an embodiment, the first pair of input channels 16 comprises a first input channel 20 that is connected to a first port 22 of the test and/or measurement instrument 12, and a second input channel 24 that is connected to a second port 26 of the test and/or measurement instrument 12. The second pair of input channels 18 comprises a third input channel 28 that is connected to a third port 30 of the test and/or measurement instrument 12, and a fourth input channel 32 that is connected to a fourth port 34 of the test and/or measurement instrument 12.

The test and/or measurement instrument 12 further comprises a real-time circuit 36 that is provided downstream of the input channels 20, 24, 28, 32, as well as a post-processing circuit 38 that is provided downstream of the real-time circuit 36.

In the example embodiment shown in FIG. 1, the test and/or measurement system 10 further comprises a first measurement probe 40 and a second measurement probe 42. In general, the measurement probes 40, 42 are each configured to pick up a respective measurement signal from the device under test 14, for example by contacting a respective corresponding contact point on the device under test 14.

For example, the first measurement probe 40 may be connected to the first port 22, such that a first analog input signal is forwarded to the first input channel 20 from the first measurement probe 40 via the first port 22. The second measurement probe 42 may be connected to the second port 26, such that a second analog input signal is forwarded to the second input channel 24 from the second measurement probe 42 via the second port 26.

As another example, the first measurement probe 40 may be connected to the first port 22, while the second measurement probe 42 may be connected to the third port 30. However, it is to be understood that any other suitable set of connections between the ports 22, 26, 30, 34 and the measurement probes 40, 42 is likewise possible.

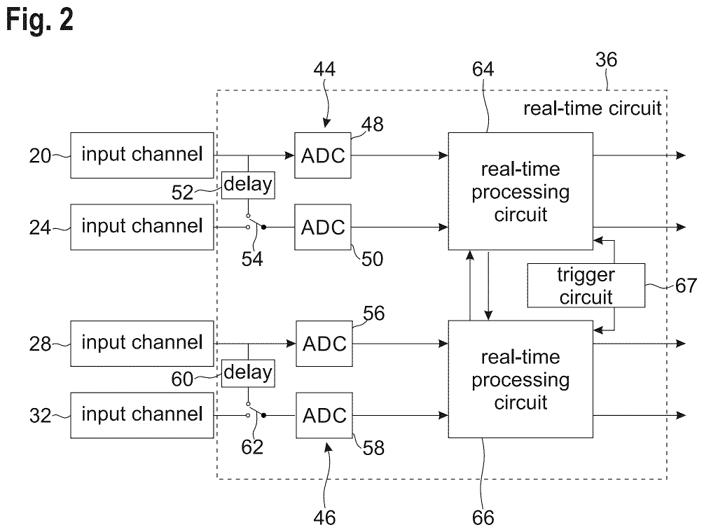

FIG. 2 schematically shows a portion of the test and/or measurement instrument 12 comprising the input channels 20, 24, 28, 32 and the real-time circuit 36 in more detail. The real-time circuit 36 comprises a first pair of ADCs 44 and a second pair of ADCs 46. It is noted that, analogously to the pairs of input channels 16, 18, the test and/or measurement instrument 12 may comprise further pairs of ADCs.

Without restriction of generality, the example embodiment shown in FIG. 2 is described hereinafter.

In an embodiment, the first pair of ADCs 44 comprises a first ADC 48 that is connected to the first input channel 20. The first pair of ADCs 44 further comprises a second ADC 50 that is selectively connectable to the second input channel 24 (directly) or to the first input channel 20 via a delay circuit 52. In an embodiment, the real-time circuit 36 may comprise a switching circuit 54 that is configured to selectively connect the second ADC 50 to the second input channel 24 or to the delay circuit 52.

In an embodiment, the second pair of ADCs 46 comprises a third ADC 56 that is connected to the third input channel 28. The second pair of ADCs 46 further comprises a fourth ADC 58 that is selectively connectable to the fourth input channel 32 (directly) or to the third input channel 28 via a further delay circuit 60. In an embodiment, the real-time circuit 36 may comprise a further switching circuit 62 that is configured to selectively connect the fourth ADC 58 to the fourth input channel 32 or to the further delay circuit 62.

In an embodiment, the real-time circuit 36 further comprises a first real-time processing circuit 64 and a second real-time processing circuit 66 that are provided downstream of the ADCs 48, 50, 56, 58. The real-time circuit 36 may comprise further real-time processing circuits.

Without restriction of generality, the example embodiment shown in FIG. 2 is described hereinafter.

The first real-time processing circuit 64 is connected to the first ADC 48 and to the second ADC 50. The second real-time processing circuit 66 is connected to the third ADC 56 and to the fourth ADC 58. Moreover, the first real-time processing circuit 64 and the second real-time processing circuit 66 are connected with each other for inter-real-time processing circuit communication, as will be described in more detail below.

In an embodiment, the test and/or measurement instrument 12 or the real-time circuit 36 may further comprise a trigger circuit 67. The trigger circuit 67 may be configured to trigger on at least one output signal of the real-time processing circuits 64, 66.

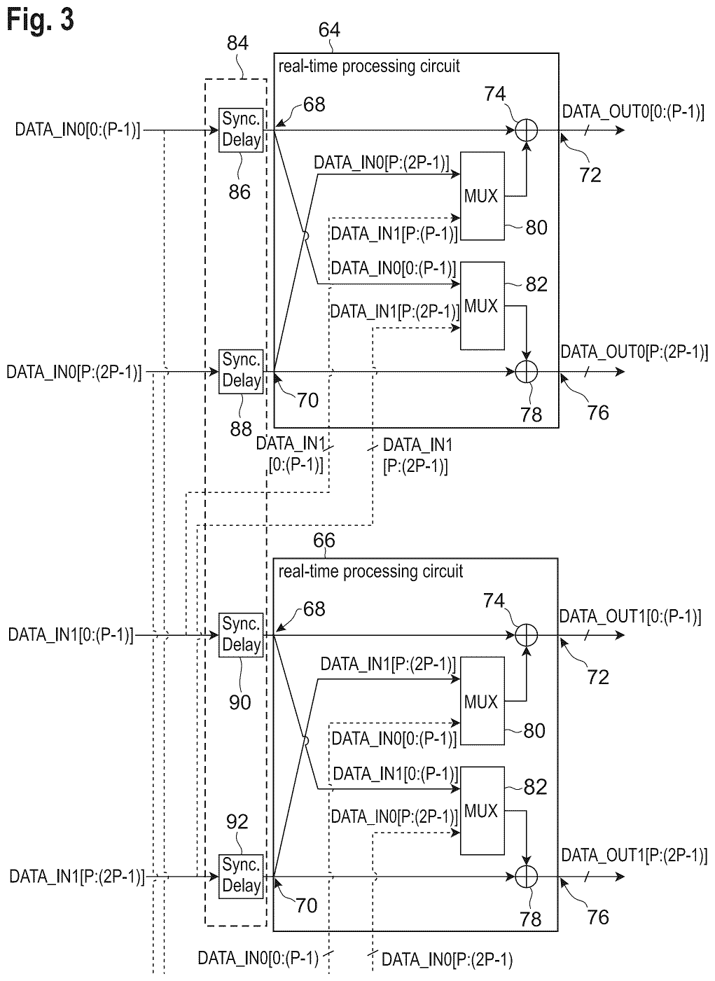

FIG. 3 shows examples of the first real-time processing circuit 64 and the second real-time processing circuit 66 in more detail. The first real-time processing circuit 64 comprises a first signal input 68 that is connected to the first ADC 48 and a second signal input 70 that is connected to the second ADC 50. The first real-time processing circuit 64 further comprises a first signal output 72 that is connected to the first signal input 68 via a first combiner circuit 74 and a second signal output 76 that is connected to the second signal input 70 via a second combiner circuit 78.

In an embodiment, the first real-time processing circuit 64 comprises a first multiplexer circuit 80 that is configured to selectively connect the second signal input 70 to the first combiner circuit 74. For example, the first multiplexer circuit 80 is configured to selectively connect the second ADC 50 or the third ADC 56 to the first combiner circuit 74.

In an embodiment, the first real-time processing circuit 64 comprises a second multiplexer circuit 82 that is configured to selectively connect the first signal input 68 to the second combiner circuit 78. For example, the second multiplexer circuit 82 is configured to selectively connect the first ADC 48 or the fourth ADC 58 to the second combiner circuit 78.

In an embodiment, the first combiner circuit 74 may be established as a summation circuit or as a subtraction circuit. Likewise, the second combiner circuit 78 may be established as a summation circuit or as a subtraction circuit. In an embodiment, the first combiner circuit 74 and/or the second combiner circuit 78 may each be adjustable to be a summation circuit or a subtraction circuit.

The second real-time processing circuit 66 is established essentially identical to the first real-time processing circuit 64. Accordingly, reference is made to the explanations given above with respect to the first real-time processing circuit 54.

In an embodiment, the first signal input 68 of the second real-time processing circuit 66 is connected to the third ADC 56, while the second signal input 70 of the second real-time processing circuit 66 is connected to the fourth ADC 58. Further, the first ADC 48 is selectively connectable to the first combiner circuit 74 of the second real-time processing circuit 66 by the first multiplexer circuit 80 of the second real-time processing circuit 66. Likewise, the second ADC 50 is selectively connectable to the second combiner circuit 78 of the second real-time processing circuit 66 by the second multiplexer circuit 82 of the second real-time processing circuit 66.

In an embodiment, the test and/or a measurement instrument 12 may further comprise a synchronization and detection circuit 84 having a first delay circuit 86 being associated with the first ADC 48, a second delay circuit 88 being associated with the second ADC 50, a third delay circuit 90 being associated with the third ADC 56, and a fourth delay circuit 92 being associated with the fourth ADC 58.

The functionality of the test and/or measurement instrument 12 in general and of the real-time circuit 36 in particular will be described hereinafter with reference to FIGS. 1-3.

In a first operational mode, the first measurement probe 40 may be, for example, connected to the first port 22 while the second measurement probe 42 may be connected to the second port 26. Accordingly, a first analog input signal is received by the first input channel 20 while a second analog input signal is received by the second input channel 24. In an embodiment, the analog input signals may correspond to a differential signal.

The first analog input signal is digitized by the first ADC 48 with a sample rate S, thereby obtaining a first digitized input signal. The second analog input signal is digitized by the second ADC 50 with the sample rate S, thereby obtaining a second digitized input signal. The first digitized input signal and the second digitized input signal are both forwarded to the first real-time processing circuit 64, namely to the first signal input 68 and to the second signal input 70, respectively.

The first real-time processing circuit 64 processes the first digitized input signal and the second digitized input signal, thereby obtaining a first output signal that is output via the first signal output 72 and a second output signal that is output via the second signal output 76.

In an embodiment, the first real-time processing circuit 64 receives a total of 2P=2S/f_{c} input signal samples, namely P=S/f_{c} input signal samples corresponding to the first analog input signal from the first ADC 48, and P=S/f_{c} input signal samples corresponding to the second analog input signal from the second ADC 50. Therein, P is a parallelism of the first real-time processing circuit 64, and f_{c} is a clock rate of the first real-time processing circuit 64.

In this embodiment, the first real-time processing circuit 64 is configured to output a total of 2P=2S/f_{c} output signal samples, namely P=S/f_{c} output signal samples corresponding to the first output signal and P=S/f_{c} output signal samples corresponding to the second output signal.

In the example embodiment shown in FIG. 3, the multiplexer circuits 80, 82 forward the respective digitized signals denoted by the solid-line arrows to the respective combiner circuits 74, 78 in the first operational mode.

For example, the first output signal may be a difference signal corresponding to the difference between the first digitized input signal and the second digitized input signal that may be obtained by the first combiner circuit 74 being established as a subtraction circuit. In an embodiment, the second output signal may be a summation signal corresponding to the sum of the first digitized input signal and the second digitized input signal that may be obtained by the second combiner circuit 78 being established as a summation circuit.

It is to be understood that obtaining a difference signal and a summation signal is purely one example. It is also conceivable that the real time processing circuit 64 may equalize the first digitized input signal and the second digitized input signal or may provide other digital signal processing functionalities.

It is also to be understood that further analog input signals may be received and processed by the second pair of input channels 18, the second pair of ADCs 46, and the second real-time processing circuit 66.

In general, in the first operational mode, the real-time processing circuits 64, 66 are configured to process N digitized input signals corresponding to N input channels, wherein each digitized input signal has a sample rate S. Therein, N is an integer being equal to or greater than 2.

In a second operational mode, the first measurement probe 40 may be, for example, connected to the first port 22 while the second measurement probe 42 may be connected to the third port 30. Accordingly, a first analog input signal is received by the first input channel 20 while a second analog input signal is received by the third input channel 28. In an embodiment, the analog input signals may correspond to a differential signal.

The first analog input signal is jointly digitized by the first ADC 48 and the second ADC 50 with an overall sample rate 2S, thereby obtaining a first digitized input signal and a second digitized input signal that both correspond to the first analog input signal. In other words, the first ADC 48 and the second ADC 50 digitize the first analog input signal in a time-interleaved manner.

The second analog input signal is jointly digitized by the third ADC 56 and the fourth ADC 58 with an overall sample rate 2S, thereby obtaining a third digitized input signal and a fourth digitized input signal that both correspond to the second analog input signal. In other words, the third ADC 56 and the fourth ADC 58 digitize the second analog input signal in a time-interleaved manner.

The four digitized input signals are then jointly processed by the first real-time processing circuit 64 and the second real-time processing circuit 66. For example, the first real-time processing circuit 64 receives a total of 2P=2S/f_{c} input signal samples, namely P=S/f_{c} input signal samples corresponding to the first analog input signal from the first ADC 48, and P=S/f_{c} input signal samples corresponding to the first analog input signal from the second ADC 50.

On the other hand, the second real-time processing circuit 64 receives a total of 2P=2S/f_{c} input signal samples, namely P=S/f_{c} input signal samples corresponding to the second analog input signal from the third ADC 56, and P=S/f_{c} input signal samples corresponding to the second analog input signal from the fourth ADC 58.

It is noted that the real-time processing circuits 64, 66 may each comprise 2P summation circuits and/or subtraction circuits.

In order to ensure that the samples corresponding to different analog input signals are correctly processed by the real-time processing circuits 64, 66, the synchronization and detection circuit 84 in an embodiment is configured to delay the respective samples received from the assigned ADCs 48, 50, 56, 58 appropriately in order to account for delays introduced by the inter-real-time processing circuit communication.

In an embodiment, the synchronization and detection circuit 84 may be configured to determine whether the different digitized input signals are forwarded to the real-time processing circuits 64, 66 in sync.

If the synchronization and detection circuit 84 detects that the different digitized input signals are out of sync, the synchronization and detection circuit 84 may control the corresponding delay circuits 86, 88, 90, 92 to adjust a delay applied to the respective digitized input signal(s).

In the example embodiment shown in FIG. 3, the multiplexer circuits 80, 82 forward the respective digitized signals denoted by the dashed arrows to the respective combiner circuits 74, 78 in the second operational mode.

Therein, for example, the output signals of the first real-time processing circuit 64 may together establish a difference signal corresponding to the difference between first analog input signal and the second analog input signal, sampled with sample rate 2S.

On the other hand, the output signals of the second real-time processing circuit 66 may together establish a summation signal corresponding to the sum of the first analog input signal and the second analog input signal, sampled with sample rate 2S.

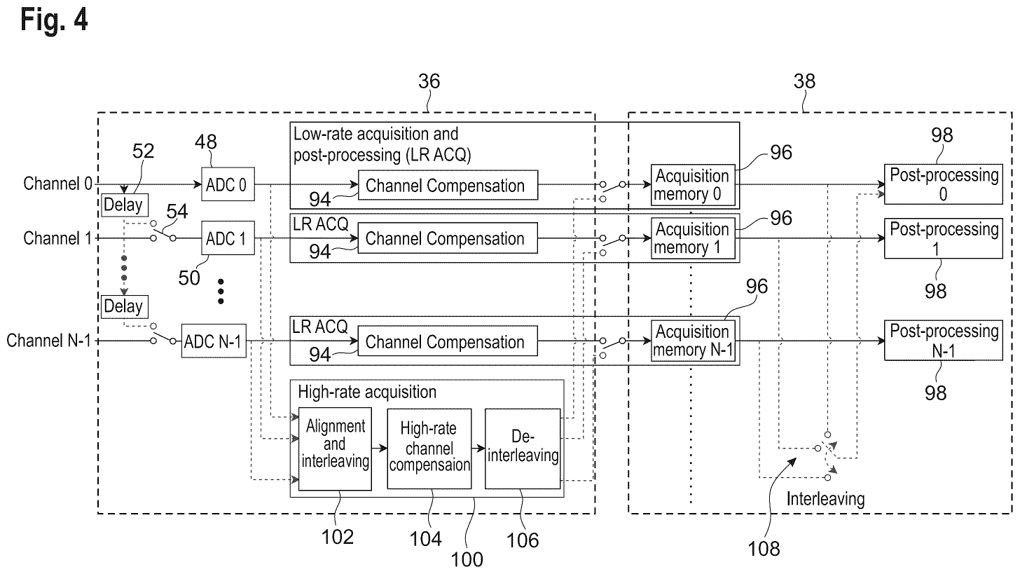

FIG. 4 schematically shows a further example embodiment of a portion of the test and/or measurement instrument 12 comprising the real-time circuit 36 and the post-processing circuit 38 in more detail. In this example embodiment, the test and/or measurement instrument 12 may be an oscilloscope, for example a digital oscilloscope. It is noted that the real-time processing circuits 64, 66 described above are not shown in this example embodiment, but may nonetheless be provided downstream of the ADCs 48, 50, 56, 58.

In the example embodiment shown in FIG. 4, the real-time circuit 36 comprises a plurality of channel compensation circuits 94, wherein each channel compensation circuit 94 is connected to one of the input channels 20, 24, 28, 32. The general compensation circuits 94 are configured to apply a channel compensation in order to correct channel effects of the respective input channel.

In an embodiment, the test and/or measurement instrument 12, for example the post-processing circuit 38, further comprises a plurality of acquisition memories 96. In the example embodiment shown in FIG. 4, the post-processing circuit 38 comprises one acquisition memory 96 per input channel.

In general, the acquisition memories 96 are configured to save the digitized input signal is obtained by the ADCs 48, 50, 56, 58. In an embodiment, the acquisition memories 96 may be established as non-volatile memories.

In an embodiment, the test and/or measurement instrument 12, for example the post-processing circuit 38, further comprises a plurality of post-processing sub-circuits 98. In an embodiment, the post-processing circuit 38 may comprise one post-processing sub-circuit 98 per input channel.

In a normal, i.e. non-interleaved, operation of the test and/or measurement instrument 12, one analog input signal can be received per input channel, be digitized by the corresponding ADC, compensated for channel effects by the channel compensation circuit 94, saved in the corresponding acquisition memory 96, and be post-processed by the corresponding post-processing sub-circuit 98.

Post-processing applied by the post-processing sub-circuits 98 can, for example, comprise spectral analysis, digital down-conversion, trace arithmetic, etc.

Of course, the test and/or measurement instrument 12 as shown in FIG. 4 does not only allow for non-interleaved operation, but alternatively or additionally for an interleaved operation of the test and/or measurement instrument 12. For this purpose, at least one high-rate acquisition circuit 100 is provided.

In an embodiment, the at least one high-rate acquisition circuit 100 comprises an interleaving sub-circuit 102, a general compensation sub-circuit 104, and a de-interleaving sub-circuit 106.

In an embodiment, the test and/or measurement instrument 12 may also comprise a distribution circuit 108 that is configured to selectively connect the acquisition memories 96 to at least one of the post-processing circuits 98.

In an embodiment, the test and/or measurement instrument 12 may be configured to selectively group the input channels 20, 24, 28, 32 into a first channel group and into a second channel group, for example in an arbitrary manner. Therein, the first channel group and the second channel group are configured to be operated independent of each other.

In the first channel group, one ADC of the plurality of ADCs 48, 50, 56, 58 is allocated per input channel belonging to the first channel group. In an embodiment, exactly one ADC of the plurality of ADCs 48, 50, 56, 58 may be allocated per input channel belonging to the first channel group. For this first channel group, individual analog input signals are processed as described above.

In the second channel group, at least two ADCs of the plurality of ADCs 48, 50, 56, 58 are allocated per input channel, which implies that at least one of the input channels 20, 24, 28, 32, for example a plurality of input channels 20, 24, 28, 32, may be deactivated. In other words, 2ⁿ ADCs of the plurality of ADCs 48, 50, 56, 58 may be allocated per input channel belonging to the second channel group, wherein n is an integer greater than or equal to 1.

In an embodiment, the at least two ADCs allocated per input channel belonging to the second channel group are configured to jointly digitize a single analog input signal received by the respective input channel belonging to the second channel group. In other words, the corresponding at least two ADCs are configured to digitize the corresponding analog input signal in a time-interleaved manner. This may be achieved by selectively connecting the corresponding ADCs to the respective input channel we are switching circuits and/or delay circuits, as described above with reference to FIG. 2.

In an embodiment, the digitized input signals obtained by the ADCs belonging to the second channel group are forwarded to the high-rate acquisition circuit 100. In an embodiment, the at least one high-rate acquisition circuit 100, for example the interleaving sub-circuit 102, is configured to interleave the digitized input signals received from the ADCs allocated to the second channel group, thereby obtaining an interleaved digitized input signal. In an embodiment, the at least one high-rate acquisition circuit 100, for example the channel compensation sub-circuit 104, further is configured to apply a channel compensation to the interleaved digitized input signal, thereby obtaining a compensated interleaved digitized input signal. In an embodiment, the at least one high-rate acquisition circuit 100, for example the de-interleaving sub-circuit 106, further is configured to de-interleave the compensated interleaved digitized input signal, thereby obtaining a plurality of compensated digitized input signals.

In an embodiment, the compensated digitized input signals are forwarded to and stored by the plurality of acquisition memories 96, for example the acquisition memories 96 that are allocated to the input channels belonging to the second channel group. From the corresponding acquisition memories 96, the compensated digitized input signals stored in the acquisition memories 96 are forwarded to at least one of the post-processing circuits 98 for post-processing, wherein the at least one of the post-processing circuits 98 may be allocated to one of the input channels belonging to the second channel group.

In an embodiment, the compensated digitized input signals stored in the acquisition memories 96 may be forwarded to the at least one of the post-processing circuits 98 in a time-interleaved manner, such that the post-processing circuit 98 receives the individual samples corresponding to the respective analog input signal in the correct order. In an embodiment, the compensated digitized input signals stored in the acquisition memories 96 may be forwarded to exactly one of the post-processing circuits 98 for post-processing.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components, such as the test and/or measurement instrument 12, the device under test 14, etc., referenced above include circuitry programmed to carry out any of, some of (in any combination), or all of, of the techniques, methodalogies or functionality disclosed herein. In an embodiment, one or more computer-readable media associated with or accessible by such circuitry contains computer readable instructions embodied thereon that, when executed by such circuitry, cause the component or circuitry to perform any of, some of (in any combination), or all of, the techniques, methodalogies or functionality disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but example of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A test and/or measurement instrument for measuring differential signals, the test and/or measurement instrument comprising:
a plurality of pairs of input channels, wherein the plurality of pairs of input channels each comprise two input channels, wherein the input channels are configured to receive a plurality of analog input signals; and
and a real-time circuit, wherein the real-time circuit comprises a plurality of pairs of analog-to-digital converters (ADCs), and at least one real-time processing circuit,
wherein each of the plurality of pairs of ADCs is allocated to one of the pairs of input channels, wherein each ADC is configured to digitize one of the analog input signals so as to obtain a digitized input signal, and
wherein the at least one real-time processing circuit has a first operational mode and a second operational mode, wherein the at least one real-time processing circuit is configured to process digitized signals of a single pair of ADCs in the first operational mode, and wherein the at least one real-time processing circuit is configured to process the digitized signals of two different pairs of ADCs in the second operational mode.

2. The test and/or measurement instrument of claim 1, wherein the plurality of pairs of ADCs comprise a first pair of ADCs being allocated to the at least one real-time processing circuit, wherein the first pair of ADCs comprises a first ADC and a second ADC, and
wherein, in the first operational mode, the first ADC is configured to digitize a first analog input signal, thereby obtaining a first digitized input signal, and the second ADC is configured to digitize a second analog input signal being different from the first analog input signal, thereby obtaining a second digitized input signal, wherein the real-time processing circuit is configured to receive the first digitized input signal and the second digitized input signal, and
wherein, in the second operational mode, the first ADC and the second ADC are configured to jointly digitize a single analog input signal, thereby obtaining a first digitized input signal and a second digitized input signal both corresponding to the single analog input signal, wherein the real-time processing circuit is configured to receive the first digitized input signal and the second digitized input signal.

3. The test and/or measurement instrument of claim 1, further comprising a trigger circuit, wherein the trigger circuit is configured to trigger on at least one output signal of the at least one real-time processing circuit.

4. The test and/or measurement instrument of claim 1, wherein the at least one real-time processing circuit comprises at least one of an adder circuit, a subtraction circuit, or an equalizer circuit.

5. The test and/or measurement instrument of claim 1, wherein a first input channel of the plurality of pairs of input channels is connectable to a first measurement probe, and wherein a second input channel of the plurality of pairs of input channels is connectable to a second measurement probe.

6. The test and/or measurement instrument of claim 1, further comprising a plurality of real-time processing circuits, wherein the plurality of real-time processing circuits is configured to process digitized input signals corresponding to N input channels with a respective predetermined sample rate in the first operational mode, wherein the at least one real-time processing circuit is configured to process digitized input signals corresponding to N/2 input channels with double the predetermined sample rate in the second operational mode, and wherein N is an integer being equal to or greater than 2.

7. The test and/or measurement instrument of claim 1, wherein the real-time circuit comprises a plurality of real-time processing circuits, wherein each of the real-time processing circuits is connected or connectable to two input channels, and wherein each real-time processing circuit is configured to receive two digitized input signals being associated with one or two of the plurality of input channels.

8. The test and/or measurement instrument of claim 1, wherein the at least one real-time processing circuit is configured to receive 2P=2S/f_{c} input signal samples, wherein the at least one real-time processing circuit is configured to output 2P=2S/f_{c} output signal samples, wherein S is a respective sample rate of the respective ADCs, wherein P is a parallelism of the at least one real-time processing circuit, and wherein f_{c} is a clock rate of the at least one real-time processing circuit.

9. The test and/or measurement instrument of claim 8, wherein the plurality of pairs of ADCs comprise a first pair of ADCs, wherein the first pair of ADCs comprises a first ADC and a second ADC,
wherein, in the first operational mode, the at least one real-time processing circuit is configured to receive P=S/f_{c} input signal samples corresponding to a first analog input signal from the first ADC and P=S/f_{c} input signal samples corresponding to a second analog input signal from the second ADC, and
wherein, in the second operational mode, the at least one real-time processing circuit is configured to receive P=S/f_{c} input signal samples corresponding to a first analog input signal from the first ADC and P=S/f_{c} input signal samples corresponding to the first analog input signal from the second ADC.

10. The test and/or measurement instrument of claim 1, further comprising a synchronization circuit, wherein the synchronization circuit is configured to synchronize digitized input signals forwarded to the at least one real-time processing circuit.

11. The test and/or measurement instrument of claim 1, further comprising a detection circuit, wherein the detection circuit is configured to determine whether different digitized input signals are forwarded to the at least one real-time processing circuit in sync.

12. An oscilloscope, comprising:
a plurality of input channels, wherein the plurality of input channels are each configured to receive an analog input signal; and
a real-time circuit, wherein the real-time circuit comprises a plurality of analog-to-digital converters (ADCs), wherein the plurality of ADCs are connected or connectable to the plurality of input channels,
wherein the oscilloscope is configured to selectively group the plurality of input channels into a first channel group and a second channel group,
wherein, in the first channel group, one ADC of the plurality of ADCs is allocated per input channel belonging to the first channel group, and
wherein, in the second channel group, at least two ADCs of the plurality of ADCs are allocated per input channel belonging to the second channel group.

13. The oscilloscope of claim 12, wherein 2n ADCs of the plurality of ADCs are allocated per input channel belonging to the second channel group, wherein n is an integer greater than or equal to 1.

14. The oscilloscope of claim 12, wherein the at least two ADCs allocated per input channel belonging to the second channel group are configured to jointly digitize a single analog input signal received by the respective input channel belonging to the second channel group.

15. The oscilloscope of claim 12, wherein the first channel group and the second channel group are configured to be operated independent of each other.

16. The oscilloscope of claim 12, wherein the real-time circuit further comprises at least one real-time processing circuit, wherein the at least one real-time processing circuit is configured to process digitized input signals corresponding to the first channel group and/or digitized input signals corresponding to the second channel group.

17. The oscilloscope of claim 12, wherein the real-time circuit further comprises at least one high-rate acquisition circuit, wherein the at least one high-rate acquisition circuit is connected to the ADCs allocated to the second channel group, and wherein the high-rate acquisition circuit is configured to interleave digitized input signals received from the ADCs allocated to the second channel group, thereby obtaining an interleaved digitized input signal.

18. The oscilloscope of claim 17, wherein the at least one high-rate acquisition circuit is configured to apply a channel compensation to the interleaved digitized input signal, thereby obtaining a compensated interleaved digitized input signal, and wherein the at least one high-rate acquisition circuit is configured to de-interleave the compensated interleaved digitized input signal, thereby obtaining a plurality of compensated digitized input signals.

19. The oscilloscope of claim 18, further comprising a plurality of acquisition memories, wherein the at least one high-rate acquisition circuit is connected to the plurality of acquisition memories, and wherein the plurality of acquisition memories is configured to store the plurality of compensated digitized input signals.

20. The oscilloscope of claim 19, further comprising a plurality of post-processing circuits and a distribution circuit, wherein the distribution circuit is interconnected between the plurality of acquisition memories and at least one of the post-processing circuits, and wherein the distribution circuit is configured to forward the plurality of compensated digitized input signals to the at least one of the post-processing circuits.
